(19) United States
(12) Patent Application Publication
(10) Pub. No.: US 2023/0193454 A1
(43) Pub. Date: Jun. 22, 2023

(54) METHOD FOR DEPOSITING A COATING ON A SUBSTRATE

(71) Applicant: OMEGA SA, Bienne (CH)

(72) Inventors: Loïc CURCHOD, Lausanne (CH); Simon SPRINGER, Berne (CH); Stephane LAUPER, Cortaillod (CH); Ahmad ODEH, Renens (CH); Marion GSTALTER, Grand'Combe Chateleu (CH); Loïc OBERSON, Morges (CH); Gregory KISSLING, La Neuveville (CH)

(73) Assignee: OMEGA SA, Bienne (CH)

(21) Appl. No.: 18/062,292

(22) Filed: Dec. 6, 2022

(30) Foreign Application Priority Data
Dec. 21, 2021 (EP) 21216464.4

(51) Int. Cl. C23C 14/14; C23C 14/00; C23C 14/35; C23C 14/58

(52) U.S. Cl. CPC C23C 14/14; C23C 14/0015; C23C 14/352; C23C 14/5813

(57) ABSTRACT

A method for depositing a coating on a substrate (100), including successively depositing a thin intermetallic layer (110) on the substrate (100), so as to obtain an external part (10), and annealing the external part (10) in a dedicated enclosure.

### CROSS-REFERENCE TO RELATED APPLICATIONS

This application claims priority to European Patent Application No. 21216464.4 filed Dec. 21, 2021, the entire contents of which are incorporated herein by reference.

### TECHNICAL FIELD OF THE INVENTION

The invention falls within the field of materials, and particularly materials defining the external appearance of external parts of timepieces, jewellery, fashion items, or more generally miscellaneous objects.

More particularly, the invention relates to a method for depositing a coating on a substrate.

### TECHNOLOGICAL BACKGROUND

Depositions of thin layers in a controlled atmosphere are commonly used in industry in general and in the watchmaking and jewellery fields in particular, to produce coatings having aesthetic and/or technical applications.

For aesthetic applications, the thin layers deposited may consist of noble metals, such as gold (Au) and silver (Ag), or noble metal alloys. These noble metal alloys often consist of a combination of gold, silver and copper (Cu), with possibly additions of platinum (Pt) or other similar metals. In these noble metal alloys, atoms form metallic bonds that are at the origin of the colour of the alloy and of its malleability.

From the thin layer deposition methods commonly used are the Physical Vapour Deposition (PVD) methods particularly comprising the cathodic sputtering method and the evaporation methods; the Chemical Vapour Deposition (CVD) methods; the galvanic growth metal deposition methods; and the Atomic Layer Deposition (ALD) methods.

Furthermore, intermetallic compounds exist, particularly of noble metals, offering a broader palette of colours in relation to the aforementioned standard noble alloys. For example, the yellow Pt—Al, orange or pink Pt—Al—Cu, blue Au—Al, violet Au—In intermetallic compounds.

In these intermetallic compounds, the atoms form strong covalent bonds that are at the origin of the particular colours of these compounds, but that make them hard and brittle in their massive form. These intermetallic compounds are therefore difficult to use and effectively rarely used in their massive form because not very malleable and difficult to shape.

These intermetallic compounds may nevertheless be used in the form of more or less thin layers by implementing one of the aforementioned vacuum thin layer deposition methods.

For example, these deposition methods may be implemented to deposit thin layers of intermetallic compounds formed from metals such as Au, Al, Cu, In or Pt, such as the compounds AuAl₂ or PtAl₂.

Nevertheless, the thin layers of intermetallic compounds deposited by these methods are outside thermodynamic equilibrium and have a mainly amorphous phase that does not have the desired colour that said intermetallic compounds of the same compositions have in their massive and crystalline form, but typically a grey colour that is not particularly aesthetically pleasing.

Indeed, the thermodynamic state of intermetallic compounds, and in particular their crystallinity and/or the presence of various phases, has a major impact on their colour for a given composition.

A step of annealing the layer in situ during the deposition method, typically at 400° C., is therefore implemented to cause a crystallisation at least partial of the intermetallic compound layer thus deposited and obtain the colouration of the layer that is specific to the crystalline phase of said intermetallic compound for the given composition.

The thin layers of intermetallic compounds in practice remain very rarely used insofar as, although they offer interesting alternatives in terms of choice of colours in relation to thin layers of standard noble alloys, the implementation of the method for depositing them is long and complex due to the fact of needing to perform an in situ annealing of the thin layers.

### SUMMARY OF THE INVENTION

The present invention resolves the aforementioned drawbacks.

To this end, the invention relates to a method for depositing a coating on a substrate, successively including:
a step of depositing a thin layer formed of an intermetallic compound on said substrate, so as to obtain an external part of a timepiece, jewellery or fashion items,
a step of annealing the external part in a dedicated enclosure different from the enclosure wherein the deposition of the thin intermetallic layer is performed.

In relation to the prior art where the annealing is carried out in situ for the deposition of the thin layer, the invention offers the advantage of being able to treat a large number of substrates simultaneously, for example in a large furnace, and therefore reduce the time of the method for each part. This approach also makes it possible to use thin layer deposition methods that do not permit in situ annealing, at least not without making the method and/or the equipment unacceptably more complicated.

In particular implementations, the invention may further include one or more of the following features, taken alone or according to any technically possible combinations.

In particular implementations, the step of depositing the thin intermetallic layer is performed by implementing a PVD deposition method from ionic or cathodic sputtering, thermal evaporation, arc or electron beam evaporation, or pulsed laser beam ablation.

In particular implementations, the deposition of the thin layer is performed from at least one target consisting of a composite of at least two metals or of at least two targets of different pure metals. In the case of the use of pure metal targets, the deposition of the thin layer is performed by co-sputtering, that is to say by simultaneous cathodic sputtering of at least two different pure metal targets, the intermetallic compound then forming when encountering at least two atom flows on the substrate. Alternatively, the deposition of the thin layer is performed by co-evaporation, that is to say simultaneous evaporation of the targets (for example in the form of powder or granules in a crucible or equivalent) of different pure metals, the intermetallic compound then forming upon encountering the atom flows coming from at least two targets on the substrate. The powers applied on the at least two targets are selected independently so that the sputtering rates of the at least two different metals result in the desired layer composition. Nevertheless, the rate for depositing the metals varies depending on the wear of the corresponding targets and the composition of the derivative layer as a consequence as said targets are used. These variations of deposition rates may be compensated by a correction of the power applied on each of the targets depending on their wear, either manually on the basis of a calibration table or automatically thanks to a feedback loop based on an in situ measurement (for example, a spectral measurement of the optical emission of the plasma in the case of the cathodic sputtering).

In the case of the use of an alloyed target, the composition of said target is selected in such a way as to directly obtain the desired layer composition on the substrate, with the advantage of not depending on the wear of said alloyed target.

In particular implementations, the deposition step is performed so that the thin intermetallic layer has a thickness between 20 and 1000 nm, preferably between 200 and 500 nm, and more preferably of 300 nm.

In particular implementations, the annealing step is performed by implementing an overall annealing operation wherein the entire thin intermetallic layer is heat treated in order to crystallise it and confer to it an expected colour.

In particular implementations, the temperature to which the external part is subjected during the overall annealing operation is between 200° C. and 500° C., and is preferably substantially equal to 300° C., for a duration between 30 and 120 minutes, and preferably of 60 minutes.

In particular implementations, the overall annealing step is performed in a conventional furnace in an ambient atmosphere or in a protective atmosphere of an inert gas, for example argon (Ar), or in a vacuum in order to avoid any chemical interaction between the thin intermetallic layer and the atmosphere.

In particular implementations, the annealing step is performed by implementing a localised annealing operation on a predetermined area of the thin intermetallic layer. Thus, a contrast of colours is obtained between the non-annealed area, mainly amorphous and grey, and the annealed area, crystallised and coloured.

In particular implementations, the annealing step is performed by implementing the localised annealing operation after the overall annealing operation.

In particular implementations, the localised annealing operation is performed by means of a laser the beam of which has a diameter between 10 μm and 100 μm, or even 50 μm and 100 μm.

In particular implementations, the localised annealing operation is performed by means of a laser configured to emit pulses the duration of which is between 4 ns and 350 ns, of variable frequency between 10 kHz and 1 MHz.

In particular implementations, the localised annealing operation is performed at ambient atmosphere, or in an enclosure in a protective atmosphere of an inert gas, for example argon (Ar), or in a vacuum in order to avoid any chemical interaction between the thin intermetallic layer and the atmosphere.

In particular implementations, the step of depositing the thin layer may be preceded by a surface structuring step wherein the surface of the substrate is structured, for example on only one portion.

In particular implementations, the portion of the structured surface of the substrate corresponds to the predetermined area subjected to the localised annealing operation, a surface appearance contrast then adding to the colour contrast for an advantageous aesthetic effect.

In particular implementations, the structuring is performed on the entire surface of the substrate that will be covered by the thin intermetallic layer.

In particular implementations, the method comprises, after the step of depositing a thin intermetallic layer and the step of overall and/or localised annealing, a step of depositing a layer for protecting the thin intermetallic layer against environmental hazards, wherein the thin intermetallic layer is covered with a stack of thin dielectric layers deposited by one or more vacuum deposition methods, such as by PVD, CVD or ALD.

In particular implementations, the thicknesses and compositions of the thin dielectric layers forming the protective stack are selected so that the interfering optical effects of said thin dielectric layers are compensated in the aim of conserving the original colour of the thin intermetallic layer.

In particular implementations, the thicknesses and compositions of the thin dielectric layers forming the protective stack are selected so that the interfering optical effects of said thin dielectric layers advantageously aesthetically modify the colour of the thin intermetallic layer, for example by increasing the saturation of the colour or by correcting the hue in a chosen direction.

In particular implementations, the protective layer is a translucent polymer layer deposited by spraying or any other method known by the person skilled in the art.

In particular implementations, the protective layer is a composite layer with combinations of polymer and dielectric layers deposited by the techniques known by the person skilled in the art.

The invention also relates, according to another aspect, to a timepiece component comprising a substrate comprising a coating deposited by implementing the aforementioned method, said timepiece component having a predetermined final colour.

### BRIEF DESCRIPTION OF THE FIGURES

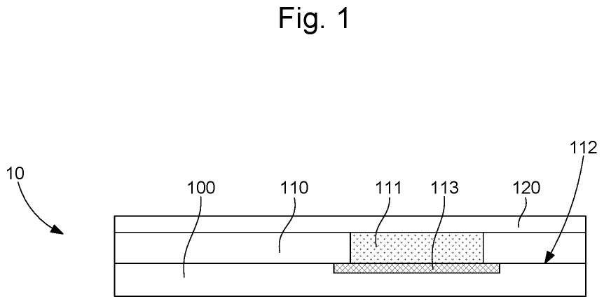

Other features and advantages of the invention will become apparent upon reading the following detailed description given by way of non-limiting example, with reference to the drawing of FIG. 1 schematically showing a sectional view of a timepiece component, such as an external part of a timepiece, including a substrate comprises a coating deposited by implementing a method for depositing an intermetallic layer according to the present invention.

### DETAILED DESCRIPTION OF THE INVENTION

The present invention relates to a method for depositing a coating on a substrate 100, said method including a step of depositing a thin intermetallic layer 110 on the substrate 100 so as to obtain an external part 10 of a timepiece, jewellery or fashion items. In particular, such an external part 10 may advantageously form a timepiece component.

The substrate 100 may be produced in any suitable material, such as in metallic material, ceramic, etc.

The method includes a step of depositing a thin intermetallic layer 110 on the substrate 100, followed by a step of annealing said external part 10 in a dedicated enclosure, so that the external part 10 has a predetermined final colour.

The step of depositing the thin intermetallic layer 110 is performed by implementing a PVD deposition method and more particularly by implementing one of the following methods: ionic or cathodic sputtering, thermal evaporation, arc or electron beam evaporation, or pulsed laser beam ablation.

The deposition of the thin intermetallic layer 110 is performed from at least two targets each consisting of a specific metal and/or from at least one target consisting of a composite of at least two metals.

Preferably, to simplify the implementation of the step of depositing the thin intermetallic layer 110, it is produced from a target consisting of a composite of at least two metals. Moreover, the results obtained during tests demonstrate that the composition of the thin intermetallic layer 110 is more reproducible when the step of depositing the thin intermetallic layer 110 is implemented from a single target consisting of a metal composite.

By way of non-limiting example, the metals used are selected from Pt, Al, Cu, In and Au, or from composites of these metals.

More specifically, the metals are for example selected so that the thin intermetallic layer 110 includes an Au—Al, Au—In, Pt—Al, or Pt—Al—Cu intermetallic combination.

The deposition step is performed so that the thin intermetallic layer 110 measures between 20 and 1000 nm of thickness, preferably between 200 and 500 nm, and more preferably 300 nm. Thus, the thin intermetallic layer 110 is advantageously opaque and has a good compromise between a thickness thick enough in order that the thin intermetallic layer 110 is adapted to withstand mechanical stresses that it is likely to undergo, and a thickness thin enough in order that the consumption of noble metals and that the duration for depositing the thin intermetallic layer 110 are not too high.

The deposition method is implemented so that the thin intermetallic layer 110 has a mainly amorphous phase after its deposition.

The parameters of the PVD deposition method, particularly the powers applied simultaneously on the various sources, are selected so that the thin intermetallic layer 110 obtained has a composition that has a desired final colour after the annealing step.

By way of non-limiting example, the thin metallic layer 110 may be made of Pt—Al—Cu composite the composition of which is Pt 61.7% by weight, Al 18.3% by weight, Cu 20.0% by weight, the deposition step of which being performed by cathodic co-sputtering from 3 pure Pt, Al and Cu targets. At the end of the deposition step, the thin intermetallic layer 110 is not very crystallised and has a colour characterised by the parameters (L*, a*, b*)=(77.5, 1.9, 2.6). Therefore, it has a very slightly pinky grey colour but without significant aesthetic advantage. After the annealing step, performed in a vacuum tube furnace at 500° C. for 2 hours, the layer crystallises so as to have a colour characterised by the parameters (L*, a*, b*)=(78.2, 10.8, 20.8). It then has a very strong and aesthetically advantageous final pinky-orange colour.

The annealing step is advantageously performed in a dedicated enclosure, different from the enclosure wherein the deposition of the thin intermetallic layer 110 is performed, that is to say different from the deposition chamber wherein the PVD deposition is performed.

The annealing step has the effect of modifying the phase of the thin intermetallic layer 110, by making it change from a mainly amorphous phase to a crystalline phase.

This solution of the present invention has the advantage of being able to be implemented by using standard equipment found on the market, and not requiring the production of expensive specific equipment for annealing the layer in situ. Furthermore, the annealing step may be performed simultaneously for a large number of external parts 10 in the same enclosure, which tends to reduce the duration of performing the method for each external part 10 and the manufacturing costs.

The annealing step may be performed by implementing an overall annealing operation wherein the entire thin intermetallic layer 110, and consequently the entire external part 10, is heat treated.

In the case of the overall annealing operation, the dedicated enclosure consists of a furnace.

The overall annealing operation is preferably carried out in a furnace in a controlled atmosphere, for example in argon or nitrogen. Alternatively, the overall annealing operation is carried out in a vacuum, the working pressure being located for example between 10⁻⁶ and 10⁻² mbar, and preferably at 10⁻⁴ mbar.

The temperature to which the external part 10 is subjected during the overall annealing operation is for example between 200° C. and 500° C., and is preferably substantially equal to 300° C. The duration of the overall annealing operation is for example between 30 and 120 minutes, and is preferably of 60 minutes.

Alternatively, the annealing step may be performed by implementing a localised annealing operation on a predetermined area 111 of the thin intermetallic layer 110.

The localised annealing operation may be performed on the thin intermetallic layer 110 directly after its deposition, that is to say when it has a mainly amorphous phase, or after the overall annealing operation, wherein the annealing is performed on the entire external part 10.

This localised annealing step has the effect of locally modifying the colour of the thin intermetallic layer 110, in order to generate a decoration, for example in the form of indexes of dials, digits, logos, etc.

The localised annealing operation is performed with the aid of a laser the beam of which may have a diameter for example between 10 μm and 100 μm, or even between 50 μm and 100 μm. The movement of the laser beam is advantageously controlled by a scanning system specific to the laser and based on mechanical or optical axes or by a scanning system specific to the substrate based on mechanical axes providing a high precision of the position of the point of impact of the laser beam on the thin intermetallic layer 110.

The laser beam has the effect of generating locally, at the point of impact with the thin intermetallic layer 110, a local rise of the temperature resulting in a local change of phase of said thin intermetallic layer 110, and consequently in a local change of colour.

The laser beam may be generated by a nanosecond pulsed or microsecond pulsed laser, or optionally by a continuous laser.

More specifically, during the localised annealing step, the laser may emit pulses of a duration between 4 ns and 350 ns, of variable frequency between 10 kHz and 1 MHz, and that may reach an average power in the order of 40 W.

Alternatively, the localised annealing step may also be implemented by using picosecond or femtosecond pulsed lasers, by using the heat accumulation effect at high rate in frequencies ranging from 100 to 200 kHz up to 10 MHz, or pulse series in bursts, as known by the person skilled in the art, spaced apart from one another from a few picoseconds to a few nanoseconds.

The wavelength of the laser beam is determined so as to favour the absorbance of the material of the thin intermetallic layer 110 that the beam is intended to impact.

By way of example, the laser beam may have a wavelength in the infra-red spectrum, in the visible spectrum or in the ultraviolet spectrum.

During the localised annealing step, the variation of the energy of the pulses of the laser beam, their repetition frequency as well as their degree of superposition result in modifying the colour of the intermetallic layer 110.

It is thus possible to create multicoloured or contrasted decorations based on a single deposition of thin intermetallic layer 110 of homogeneous composition.

Advantageously, the steps of depositing and annealing the thin intermetallic layer may be preceded by a step of structuring the surface 112 of the substrate 100 wherein a portion of the surface 112 of the substrate 100 is structured, and is called “structured portion 113” in the remainder of the text, so as to generate a surface structure contrast on said surface 112.

The structured portion 113 of the surface 112 of the substrate 100 may correspond to the predetermined area 111 of the intermetallic layer 110 that is subjected to the heat treatment during the localised annealing operation. This has the advantageous effect of reinforcing the difference between the visual appearance of said predetermined area 111 and that of the rest of the thin intermetallic layer 110.

Alternatively, in an alternative embodiment of the invention, the structuring is performed on the entire surface 112 of the substrate 100.

Such a surface structuring step may consist for example in polishing, matt finishing or satin finishing partially or totally the surface 112 of the substrate 100, according to the alternative embodiment considered.

In order to facilitate the localised annealing step and reduce the local contribution of heat needed to carry out the phase transformation of the thin intermetallic layer, the external part 10 may be preheated to a temperature that is close to the phase transition temperature. Thus the supplementary energy contribution by laser may be reduced.

Advantageously, the thin intermetallic layer 110 obtained after the deposition step may be covered with a protective layer 120, for example formed by a stack of thin dielectric layers intended to protect the thin intermetallic layer 110 against environmental hazards, during a subsequent deposition step that may advantageously be performed with the same deposition equipment as that used to implement the step for depositing the thin intermetallic layer 110. This stack of thin dielectric layers may also have the effect of modifying the visual appearance of the external part 10, for example by increasing the brightness thereof, and/or by modifying the colour of the intermetallic layer 110 by an advantageous interference effect.

The step of depositing a protective layer 120 is advantageously the last step of the method according to the invention.

The stack of thin dielectric layers may be formed of various oxides, nitrides, oxynitrides, such as TiO₂, Al₂O₃, SiO₂, SiN, Si3N4, and may be deposited by an ALD and/or PVD and/or CVD deposition method.

Alternatively, the step of depositing a protective layer 120 may consist in depositing a varnish layer, for example a polymer varnish layer of the zapon or parylene type.

Globally, if the method according to the invention includes all of the aforementioned steps, they are implemented successively by starting with the step of structuring the surface of the substrate 100, then the step of depositing the thin intermetallic layer 110 is performed, followed by the overall annealing step and/or the localised annealing step, and finally the step of depositing the protective layer 120.

The invention thus proposes a solution for the use of intermetallic compounds, particularly based on noble metals, offering a wide range of new colours for aesthetic applications in watchmaking, jewellery and any other luxury product.

More generally, it should be noted that the implementations and embodiments considered above have been described by way of non-limiting examples, and that other variants are consequently possible.

1. A method for depositing a coating on a substrate (100), said method comprising:
a step of depositing a thin intermetallic layer (110) on said substrate (100), so as to obtain an external part (10) of a timepiece, jewellery or fashion items,
a step of annealing the external part (10) in a dedicated enclosure different from the enclosure wherein the deposition of the thin intermetallic layer (110) is performed.

2. The method according to claim 1, wherein the step of depositing the thin intermetallic layer (110) is performed by implementing a PVD deposition method from cathodic or ionic sputtering, thermal evaporation, arc or electron beam evaporation, or pulsed laser beam ablation.

3. The method according to claim 2, wherein the deposition of the thin layer is performed from at least one target consisting of a composite of at least two metals or of at least two targets of different pure metals.

4. The method according to claim 1, wherein the deposition step is performed so that the thin intermetallic layer (110) has a thickness between 20 and 1000 nm, preferably between 200 and 500 nm, and more preferably of 300 nm.

5. The method according to claim 1, wherein the annealing step is performed by implementing an overall annealing operation wherein the entire thin intermetallic layer (110) is heat treated.

6. The method according to claim 5, wherein the temperature to which the external part (10) is subjected during the overall annealing operation is between 200° C. and 500° C., and is preferably substantially equal to 300° C., fora duration between 30 and 120 minutes, and preferably of 60 minutes.

7. The method according to claim 1, wherein the annealing step is performed by implementing a localised annealing operation on a predetermined area (111) of the thin intermetallic layer (110).

8. The method according to claim 5, wherein the annealing step is performed by implementing a localised annealing operation on a predetermined area (111) of the thin intermetallic layer (110) after the overall annealing operation.

9. The method according to claim 7, wherein the localised annealing operation is performed by means of a laser the beam of which has a diameter between 10 μm and 100 μm.

10. The method according to claim 7, wherein the localised annealing operation is performed by means of a laser configured to emit pulses the duration of which is between 4 ns and 350 ns, of variable frequency between 10 kHz and 1 MHz.

11. The method according to claim 1, wherein the step of depositing the thin intermetallic layer (110) may be preceded by a surface structuring step wherein the surface (112) of the substrate (100) is structured.

12. The method according to claim 11, wherein only one portion of the surface (112) of the substrate (100) is structured, the structured portion (113) corresponding to a predetermined area (111) of the thin intermetallic layer (110) subjected to a localised annealing operation.

13. The method according to claim 11, wherein the surface structuring is performed on the entire surface (112) of the substrate (100).

14. The method according to claim 1, further comprising, after the step of depositing the thin intermetallic layer (110) and the step of overall and/or localised annealing, a step of depositing a protective layer (120).

15. The method according to claim 14, wherein during the step of depositing a protective layer (120), the thin intermetallic layer (110) is covered by a stack of thin dielectric layers and/or by a translucent polymer layer.

16. The method according to claim 15, wherein the composition and the thickness of the thin dielectric layers of the protective stack (120) are specifically selected to conserve the original colour of the thin intermetallic layer (110) or to advantageously modify the colour of the thin intermetallic layer (110) in a chosen direction.

17. A timepiece component comprising a substrate (100), wherein said substrate (100) comprises a coating deposited by implementing a method according to claim 1, said component having a predetermined final colour.
